(19) United States
(12) Patent Application Publication
(10) Pub. No.: US 2015/0159049 A1
(43) Pub. Date: Jun. 11, 2015

(54) POLISHING AGENT AND POLISHING METHOD

(71) Applicant: Asahi Glass Company, Limited, Chiyoda-ku (JP)

(72) Inventor: Yoshiharu Amano, Chigasaki-shi (JP)

(73) Assignee: Asahi Glass Company, Limited, Chiyoda-ku (JP)

(21) Appl. No.: 14/557,755

(22) Filed: Dec. 2, 2014

(30) Foreign Application Priority Data
Dec. 11, 2013 (JP) 2013-255925

(51) Int. Cl. C09G 1/02; H01L 21/306

(52) U.S. Cl. CPC C09G 1/02; H01L 21/30625

(57) ABSTRACT

A polishing agent contains cerium oxide particles; water, and a monocarboxylic acid and/or a salt thereof, the monocarboxylic acid having a five-membered ring not including an unsaturated bond in the ring or a derivative thereof, a pH of the polishing agent is 3.5 or more to 7 or less. As the monocarboxylic acid, a tetrahydrofuran-2-carboxylic acid, a cyclopentane carboxylic acid, or the like can be used.

### CROSS REFERENCE TO RELATED APPLICATION

This application is based upon and claims the benefit of priority from the prior Japanese Patent Application No. 2013-255925, filed on Dec. 11, 2013; the entire contents of which are incorporated herein by reference.

### FIELD

The present invention relates generally to a polishing agent and a polishing method, and relates particularly to a polishing agent for chemical mechanical polishing in manufacturing of a semiconductor integrated circuit and a polishing method using that polishing agent.

### BACKGROUND

In recent years, because of a tendency of high integration and high function of a semiconductor integrated circuit, development of a microfabrication technique for miniaturization and high density of a semiconductor element is advanced. Conventionally, in manufacturing of a semiconductor integrated circuit (hereinafter, also referred to as a semiconductor device), planarization of an interlayer insulation film, an embedded wiring, or the like is carried out by using chemical mechanical polishing (hereinafter, referred to as CMP), in order to prevent a problem that unevenness (level difference) of a layer surface exceeds a depth of focus of lithography and hampers obtaining a sufficient resolution. Importance of high planarization by CMP increases all the more as demand for high resolution or miniaturization of an element becomes severer.

Further, in manufacturing of a semiconductor device, a isolation method (shallow trench isolation, hereinafter, referred to as STI) by a shallow trench with a small element isolation width is introduced in recent years in order to advance more sophisticated miniaturization of a semiconductor element.

STI is a technique to form an electrically insulated element region by forming a trench in a silicon substrate and embedding an insulation film in the trench. In STI, first, as shown in FIG. 1A, after an element region of a silicon substrate 1 is masked by a silicon nitride film 2 or the like, a trench 3 is formed in the silicon substrate 1 and an insulation film such as a silicon dioxide film 4 or the like is deposited to fill the trench 3. Next, by CMP, the silicon dioxide film 4 on the silicon nitride film 2 being a convex part is polished and removed while the silicon dioxide film 4 in the trench 3 being a concave part is left, whereby an element isolation structure in which the silicon dioxide film 4 is embedded in the trench 3 is obtained as shown in FIG. 1B.

In STI CMP, as a result of enhancing a selectivity (meaning a ratio of a polishing rate of a silicon dioxide film to a polishing rate of a silicon nitride film, hereinafter, also referred to simply as a selectivity) between the silicon dioxide film and the silicon nitride film, progress of polishing can be suppressed at a time that the silicon nitride film is exposed. As described above, in a polishing method using a silicon nitride film as a stopper film, a smoother surface can be obtained compared with a conventional polishing method.

As described above, in a recent CMP technology, not only a high polishing rate of a silicon dioxide film is demanded in view of a cost, but also high selectivity is important. However, in conventional polishing by silica abrasives, control of the selectivity, to which a chemical polishing characteristic largely contributes, is not able to be sufficiently performed because of a characteristic of physical polishing due to high hardness of silica. Thus, for CMP in which a particularly high selectivity is demanded, cerium oxide particles are used as abrasive particles. It is also known that the cerium oxide particle, having lower hardness compared with a silica particle, is hard to generate a defect in polishing (hereinafter, referred to as a polishing defect) and has a specifically high polishing rate of a silicon oxide.

In a polishing agent containing cerium oxide particles as abrasive particles, a method for further improving a polishing characteristic is proposed. In Japanese Patent Publication No. JP-B2 4927526, there is proposed a polishing agent which contains an additive selected from a group composed of an arylamine such as an aniline, a heterocyclic amine such as an imidazole and a quinoline, an aminocarboxylic acid such as an aspartic acid, a, cyclic monocarboxylic acid such as a cyclohexane carboxylic acid and a cyclohexyl acetic acid, and a salt thereof, and whose pKa is 4 to 9.

Further, in International Publication No. WO 2004/010487 A1, there is proposed a polishing agent for semiconductor which contains a cerium oxide abrasive particle, water, and a water-soluble organic polymer or an anionic surfactant. Further, it is described that ammonium polyacrylate is contained.

Further, Japanese Patent Publication No. JP-A 2010-87454 discloses a polishing agent for CMP containing cerium oxide particles, an additive, and water, the polishing agent including, as the additive, an aromatic heterocyclic compound having an aromatic heterocycle containing an oxygen atom or a sulfur atom and a carboxyl group bonded to a specific position of the aromatic heterocycle. Further, as the aromatic heterocyclic compound, a 2-thiophencarboxylic acid and a 2-furancarboxylic acid are exemplified.

However, by each of the polishing agents described in the above-mentioned publications, it is difficult to suppress a polishing rate of a silicon nitride film at a low level while maintaining a sufficiently high polishing rate of a silicon dioxide film, and it is difficult to achieve a high selectivity.

In other words, among the polishing agents described in Patent Publication No. JP-B2 4927526, for example, the polishing agent containing the cyclohexane carboxylic acid being a carboxylic acid having a six-membered ring in a molecule secures a high value, in selectivity between a silicon dioxide film and a silicon nitride film, but a polishing rate of the silicon dioxide film is not sufficient. Since in recent years particularly, a particle diameter of cerium oxide particles is made small and a polishing pad with low hardness is used in view of suppressing a polishing defect, a tendency of an insufficient polishing rate is becoming increasingly prominent. Further, in the polishing agent of Patent Publication No. JP-B2 4927526, securing dispersion stability of the cerium oxide particles is hard depending on a kind of the additive, and, for example, in the poling agent containing the cyclohexane carboxylic acid, since a hydrophilicity of the cyclohexane carboxylic acid is low, there is a problem that handling as an aqueous polishing agent is difficult.

In each of the polishing agents described in International Publication No. WO 2004/010487 A1 and Japanese Patent Publication No. JP-A 2010-87454, it is difficult to suppress the polishing rate of the silicon nitride film at a low level while maintaining the sufficiently high polishing rate of the silicon dioxide film and to achieve a high selectivity.

### BRIEF DESCRIPTION OF THE DRAWINGS

FIG. 1A and FIG. 1B are cross-sectional views of a semiconductor substrate showing a method of polishing by STI CMP; and

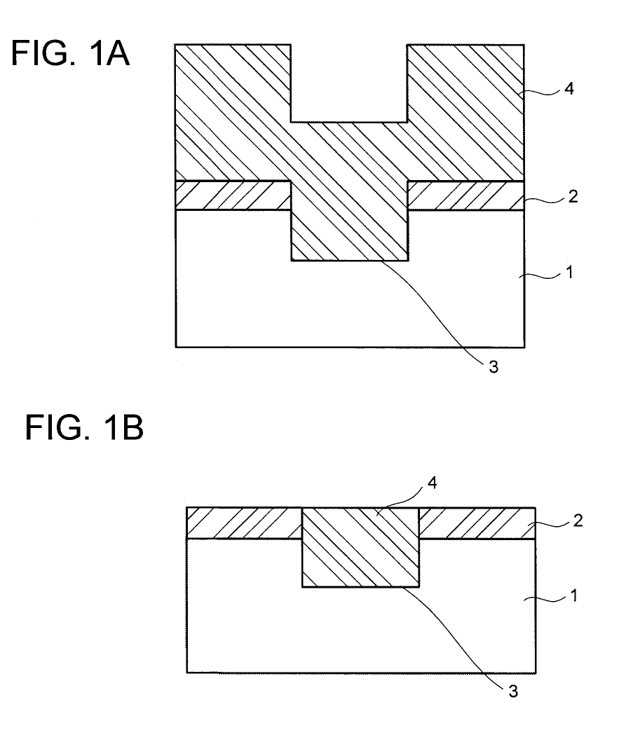

FIG. 2 is a diagram showing an example of a polishing apparatus usable for a polishing method of the present invention.

### DETAILED DESCRIPTION

The present invention is made to solve the above-described problem, and an object thereof is to provide a polishing agent capable of suppressing a polishing rate of a silicon nitride film at a low level while maintaining a sufficiently high polishing rate of a silicon oxide film such as a silicon dioxide film to achieve a high selectivity, as well as a polishing method.

The polishing agent of the present invention comprises cerium oxide particles, water, and a monocarboxylic acid having a five-membered ring not including an unsaturated bond in the ring or a derivative thereof, and/or a salt of the monocarboxylic acid, wherein a pH is 3.5 or more to 7 or less.

In the polishing agent of the present invention, the monocarboxylic acid is preferable to be at least one selected from a tetrahydrofuran-2-carboxylic acid and a cyclopentane carboxylic acid. Further, a content ratio of the monocarboxylic acid and/or its salt is preferable to be 0.001 mass % or more to 1.0 mass % or less. Further, a content ratio of the cerium oxide particle is preferable to be 0.05 mass % or more to 5 mass % or less.

The polishing method of the present invention comprises polishing by a relative motion between a surface to be polished and a polishing pad which are brought into contact with each other while a polishing agent is supplied, wherein a surface to be polished including a surface made of a silicon oxide of a semiconductor substrate is polished by using the polishing agent of the present invention.

In the present invention, a “surface to be polished” means a surface to be polished of a polishing target, and means a front surface, for example. In this specification, the “surface to be polished” includes a surface in an intermediate stage appearing in a semiconductor substrate in manufacturing a semiconductor device. Further, in the present invention, a “silicon oxide” concretely means a silicon dioxide, but is not limited thereto and includes the silicon oxide other than the silicon dioxide.

According to the polishing agent and the polishing method of the present invention, in CMP of a surface to be polished including a surface made of a silicon oxide, for example, it is possible to suppress a polishing rate of a silicon nitride film at a low level while maintaining a sufficiently high polishing rate of a silicon oxide film, achieving a high selectivity between the silicon oxide and a silicon nitride.

Hereinafter, embodiments of the present invention will be described. The present invention is not limited to the following embodiments, and another embodiment can also belong to the category of the present invention as long as the embodiment complies with the spirit of the present invention.

<Polishing Agent>

A polishing agent of the present invention contains cerium oxide particles, water, a monocarboxylic acid (hereinafter, referred to as a monocarboxylic acid (A)) having a five-membered ring not including an unsaturated bond (double bond) in the ring or a derivative thereof, and/or its salt. Besides, a pH of this polishing agent is adjusted within a range of 3.5 or more to 7 or less.

When the polishing agent of the present invention is used for CMP of a surface to be polished including a silicon oxide film (for example, a silicon dioxide film) in STI, a polishing rate of the silicon oxide film is high, and in addition, a polishing rate of a silicon nitride film is sufficiently low, so that a high selectivity between the silicon oxide film and the silicon nitride film can be achieved.

A detailed mechanism in which the polishing agent of the present invention exhibits such an excellent polishing characteristic is not exactly known, but it is conceived that the excellent polishing characteristic is caused by that a carboxyl group of the monocarboxylic acid (A) and/or its salt contained in the polishing agent of the present invention is absorbed specifically to a surface of the cerium oxide particle in a region of 3.5 or more to 7 or less in pH. It is inferred that as a result of reforming of a surface state of the cerium oxide particle by such absorption, the polishing rate of the silicon oxide film such as a silicon dioxide film is improved. Further, it is conceived that, since the monocarboxylic acid (A) has the five-membered ring in a molecule and the five-membered ring has a structure which does not include the unsaturated bond such as a double bond of carbon-carbon or a double bond of carbon and a heteroelement (for example, O, S, N) in the ring, an effect of the aforementioned absorption of the carboxyl group to the cerium oxide particle surface and reforming of the particle surface thereby is optimized, enabling achievement of both the high polishing rate of the silicon oxide film and the high selectivity between the silicon oxide film and silicon nitride film without impairing dispersibility of the cerium oxide particles.

Hereinafter, each component contained in the polishing agent of the present invention, and a pH of a polishing agent will be described.

(Cerium Oxide Particles)

In the polishing agent of the present invention, the cerium oxide particles to be contained are not particularly limited. For example, cerium oxide particles manufactured by a method described in JP-A11-12561 or JP-A 2001-35818 can be used. In other words, there can be used cerium oxide particles obtained as a result that a cerium hydroxide gel is fabricated by adding an alkali to a cerium (IV) nitride ammonium aqueous solution and that the cerium hydroxide gel is filtrated, washed, and calcined, or cerium oxide particles obtained as a result that a high-purity cerium carbonate is ground and thereafter calcined, and further milled and classified. Further, as described in JP-A 2010-505735, one made by chemically oxidizing a cerium (III) salt in a liquid can be used.

An average particle diameter of the cerium oxide particles is preferable to be 0.001 μm or more to 0.5 μm or less, and is particularly preferable to be 0.03 μm or more to 0.3 μm or less. When the average particle diameter exceeds 0.5 μm, there is a possibility that a polishing defect such as a scratch occurs in a surface to be polished. Further, when the average particle diameter is less than 0.001 μm and too small, there is a possibility that a polishing rate is reduced, and in addition, because of largeness of a proportion of a surface area per unit volume, the cerium oxide particles are apt to be influenced by a surface state, and are apt to be aggregated depending on a condition such as a pH and a concentration of an additive.

For measurement of the average particle diameter, a particle size distribution analyzer of a laser diffraction/scattering type, a dynamic light scattering type, a photon correlation type, or the like can be used. When the particle diameter is large in some measure and apt to precipitate, the particle size distribution analyzer of the laser diffraction/scattering type is preferable. Note that the above-described range is a preferable range in a case of measurement by using the particle size distribution analyzer of the laser diffraction/scattering type and that a preferable range by measurement by the dynamic light scattering type or the photon correlation type is the same.

A content ratio (concentration) of the cerium oxide particle is preferable to be 0.05 mass % or more to 5.0 mass % or less in relation to an entire mass of the polishing agent, and is particularly preferable to be within a range of 0.1 mass % or more to 2.0 mass % or less. When the content ratio of the cerium oxide particles is 0.05 mass % or more to 5.0 mass % or less, a sufficiently high polishing rate of a silicon oxide film can be obtained. Further, a viscosity of the polishing agent is not too high, and handleability is good.

With regard to the cerium oxide particles, ones in a state of being dispersed in a medium in advance (hereinafter, referred to as a cerium oxide dispersion liquid) may be used. As the medium, water can be preferably used. The cerium oxide dispersion liquid may contain a dispersant in order to obtain a more stable dispersion state. As the dispersant, there can be cited an inorganic acid, an inorganic acid salt, an organic acid, an organic acid salt, an anionic, cationic, nonionic, or amphoteric surfactant, an anionic polymer, a cationic polymer, a nonionic polymer, and so on, and one kind or two or more kinds thereof can be used.

For preparation of the cerium oxide dispersion liquid, an ultrasonic dispersion machine, a wet jet mill, a cavitation mill, or the like can be used. The ultrasonic dispersion machine is an apparatus disintegrating an aggregate by energy of an ultrasonic wave and dispersing abrasive particles in water, and, for example, an ultrasonic homogenizer US series manufactured by NIHON SEIM Co., and so on can be used. The wet jet mill is an apparatus colliding abrasive particles against each other to disintegrate an aggregate by kinetic energy of collision and dispersing the abrasive particles in water, and, for example, Star Burst manufactured by Sugino Machine Ltd., and so on can be cited. The cavitation mill is an apparatus dispersing abrasive particles in water by an action of a high-speed shear force, cavitation, or the like, and, for example, NanoVater manufactured by YOSHIDA KIKAI CO., LTD., and so on can be used.

(Water)

In the polishing agent of the present invention, water is contained as the medium dispersing the cerium oxide particles. A content of water is preferable to be 50 mass % or more to 99.9 mass % or less in relation to the entire polishing agent, and is further preferable to be 80 mass % or more to 99.9 mass % or less, and is particularly preferable to be 90 mass % or more to 99 mass % or less. Water is not particularly limited, but it is preferable to use pure water, ultrapure water, ion-exchange water, or the like in view of influence to another component, prevention of mixture of impurities, influence to a pH, and so on.

(Monocarboxylic Acid (A) and/or its Salt)

The polishing agent of the present invention contains a monocarboxylic acid (A) which has a five-membered ring not including an unsaturated bond in the ring or a derivative thereof and in which a carboxyl group is bonded to a carbon atom constituting the five-membered ring, and/or a salt of the monocarboxylic acid (A). As a result that the polishing agent contains such a monocarboxylic acid (A) and/or its salt, a surface state of a cerium oxide particle being an abrasive particle is improved, and improvement of a polishing rate of a silicon oxide film (for example, a silicon dioxide film) and improvement of a selectivity between the silicon oxide film and a silicon nitride film can be achieved.

Here, the derivative of the five-membered ring means a derivative in which a substituent other than a carboxyl group is directly bonded to a carbon atom constituting a ring of a five-membered ring. As the substituent other than the carboxyl group to be bonded to the carbon atom, there can be used an alkyl group with a carbon number of 1 to 4 such as a methyl group and an ethyl group, an alkoxy group with a carbon number of 1 to 4 such as a methoxy group and an ethoxy group, a hydroxyl group, an oxo group, halogen, and so on. The monocarboxylic acid (A) having the five-membered ring or the derivative of the five-membered ring as above is a monovalent carboxylic acid which has a five-membered ring or a derivative thereof in a molecule and has a carboxyl group. The carboxyl group is preferable to be directly bonded to the carbon atom constituting the five-membered ring.

Further, as the salt of such a monocarboxylic acid (A), there can be used an ammonium salt, a quaternary ammonium salt, an alkali metal salt such as a potassium salt, and an alkali earth metal salt such as a calcium salt, a magnesium salt, and a barium salt.

In terms of improvement of a polishing rate of a silicon oxide film such as a silicon dioxide film, and a selectivity, the aforementioned monocarboxylic acid (A) is preferable to be at least one selected from a tetrahydrofuran-2-carboxylic acid represented by a formula (1) below, a cyclopentane carboxylic acid represented by a formula (2), and a 5-oxotetrahydrofuran-2-carboxylic acid represented by a formula (3), and is particularly preferable to be at least one selected from the tetrahydrofuran-2-carboxylic acid and the cyclopentane carboxylic acid.

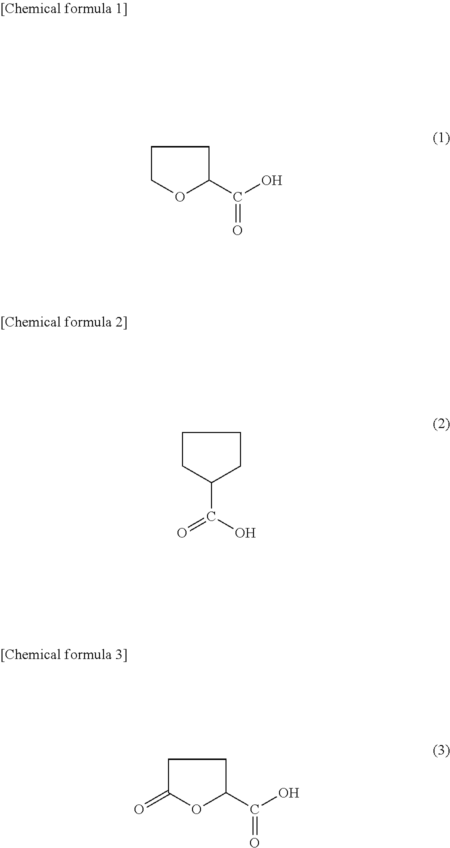 [SMILES: O=C(O)C1CCCO1 ; O=C(O)C1CCCC1 ; O=C1CCC(C(=O)O)O1]

A content ratio (concentration) of the above-described monocarboxylic acid (A) and/or its salt is preferable to be 0.001 mass % or more to 1.0 mass % or less in relation to the entire polishing agent. When the content ratio is within the above-described range, an improvement effect of the polishing rate of the silicon oxide film and the selectivity can be obtained sufficiently, and dispersion stability of the cerium oxide particles is also good. The content ratio of the monocarboxylic acid (A) and/or its salt is more preferable to be 0.01 mass % or more to 0.5 mass % or less in relation to the entire polishing agent, and is particularly preferable to be 0.02 mass % or more to 0.1 mass % or less.

(pH)

A pH of the polishing agent of the present invention is preferable to be 3.5 or more to 7 or less. When the pH of the polishing agent is within the above-described range, an improvement effect of the polishing rate of the silicon oxide film and the selectivity can be obtained sufficiently, and dispersion stability of the cerium oxide particles is also good. The pH of the polishing agent is more preferable to be 3.5 or more to 6.5 or less, and is further preferable to be 4 or more to 5.5 or less. Note that a pH of a liquid somewhat changes depending on a liquid temperature, and the pH of the polishing agent is a value at 25° C.

The polishing agent of the present invention may contain various kinds of inorganic acids or inorganic acid salts as a pH adjusting agent, in order to make the pH be a predetermined value. The inorganic acid or the inorganic acid salt is not particularly limited, and there can be used, for example, a nitric acid, a sulfuric acid, a hydrochloric acid, a phosphoric acid, a boric acid, a carbonic acid, and an ammonium salt thereof or a potassium salt thereof, and so on. Further, it is possible to add various kinds of basic compounds as the pH adjusting agent to the polishing agent. The basic compound is preferable to be water-soluble, but is not particularly limited. It is possible to use, for example, ammonia, potassium hydroxide, and quaternary ammonium hydrorxide such as tetramethylammonium hydroxide (TMAH) and tetraethylammonium hydroxide, monoethanolamine, ethylene diamine, and so on.

The polishing agent of the present invention can contain an aggregation preventing agent or a dispersant, other than the above-described component. The dispersant is contained in order to disperse cerium oxide particles stably in a dispersion medium such as pure water. As the dispersant, there can be used an anionic, cationic, nonionic, or amphoteric surfactant, and an anionic, cationic, nonionic, or amphoteric high molecular compound, and one kind or two or more kinds of the above can be contained. Further, the polishing agent of the present invention can properly contain a lubricant, a viscosity imparting agent or a viscosity adjusting agent, an antiseptic agent, or the like, as necessary.

In order to prepare the polishing agent of the present invention, a method is used in which the cerium oxide dispersion liquid and the monocarboxylic acid (A) and/or its salt are added and mixed to water such as pure water and ion-exchange water. After mixing, stirring is carried for predetermined time by using a stirrer or the like, whereby a homogeneous polishing agent can be obtained. Further, it is possible to obtain a better dispersion state by using an ultrasonic dispersion machine after mixing.

In the polishing agent of the present invention, concentrations of the cerium oxide particles and the monocarboxylic acid (A) and/or its salt may be condensed to be about ten times a concentration at a time of usage of the polishing agent, for example, and be diluted to have a predetermined concentration at the time of usage, for the sake of convenience of storage or transportation. Further, it is possible to separately prepare the cerium oxide dispersion liquid and an aqueous solution including the monocarboxylic acid (A) and/or its salt and to mix the above at the time of usage to obtain a predetermined concentration.

<Polishing Method>

A polishing method of the present invention is a method of performing polishing by a relative motion between a surface to be polished and a polishing pad which are brought into contact with each other while the polishing agent described above is supplied. Here, the surface to be polished to which polishing is performed is a surface including a surface made of silicon dioxide of a semiconductor substrate, for example. As the semiconductor substrate, the substrate for STI described above can be used as a preferable example. The polishing agent of the present invention is also effective to polishing for planarization of an interlayer insulation film between multilayer wirings.

As the silicon dioxide film in the substrate for STI, there can be used what is called a PE-TEOS film which is film-formed from tetraethoxysilane (TEOS) by a plasma CVD method. Further, as the silicon dioxide film, what is called an HDP film which is film-formed by a high density plasma CVD method can also be exemplified. As the silicon nitride film, there can be used a film which is film-formed from silane or dichlorosilane and ammonia by a low pressure CVD method or a plasma CVD method.

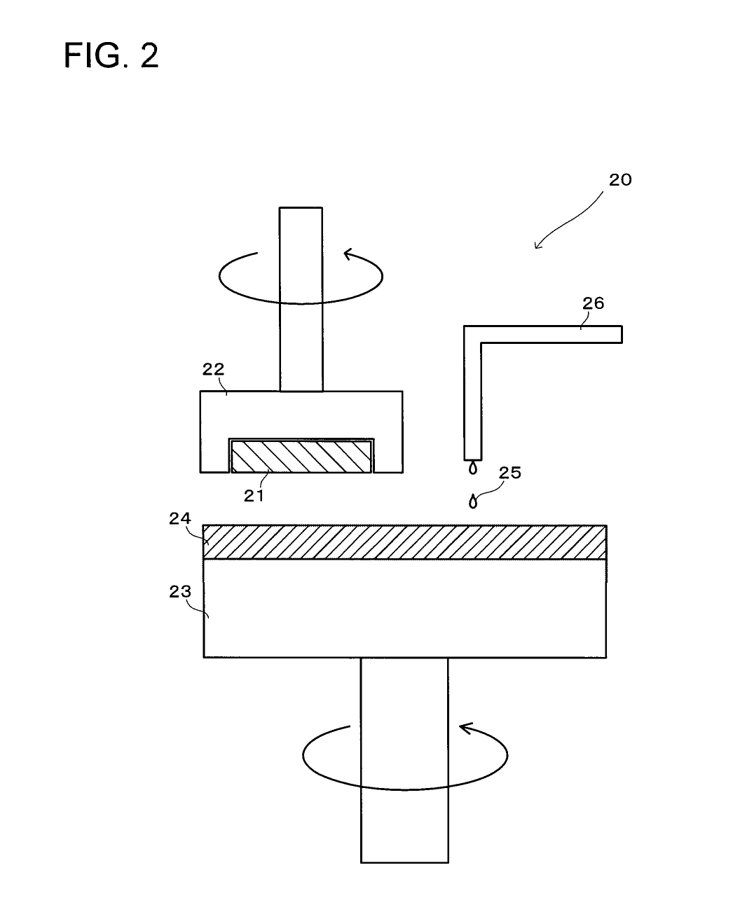

In the polishing method of the present invention, a known polishing apparatus is usable. FIG. 2 is a diagram showing an example of the polishing apparatus usable in the polishing method of the present invention.

A polishing apparatus 20 has a polishing head 22 to hold a semiconductor substrate 21 such as an STI substrate, a polishing platen 23, a polishing pad 24 set on a surface of the polishing platen 23, and a polishing agent supply piping 26 to supply a polishing agent 25 to the polishing pad 24. It is configured that a surface to be polished of the semiconductor device 21 held by the polishing head 22 is brought into contact with the polishing pad 24 to perform polishing by a relative rotational motion of the polishing head 22 and the polishing platen 23 while the polishing agent 25 is being supplied from the polishing agent supply piping 26. Note that the polishing apparatus used in the embodiment of the present invention is not limited to one having such a structure.

The polishing head 22 may make not only a rotational motion but also a linear motion. Further, the polishing platen 23 and the polishing pad 24 may have a size nearly equal to or smaller than a size of the semiconductor substrate 21. In that case, it is preferable to configure that all of the surface to be polished of the semiconductor substrate 21 is able to be polished by a relative motion of the polishing head 22 and the polishing platen 23. Further, the polishing platen 23 and the polishing pad 24 are not necessarily ones which make rotational motions, and may be ones which move in one direction by a belt system, for example.

A condition of polishing by such a polishing apparatus 20 is not particularly limited, and a polishing pressure can be further heightened to improve the polishing rate by giving a load to the polishing head 22 in pressing against the polishing pad 24. The polishing pressure is preferable to be about 0.5 to 50 kPa, and is more preferable to be about 3 to 40 kPa in view of uniformity of the polishing rate, flatness, and prevention of a polishing defect such as a scratch in the surface to be polished of the semiconductor device 21. The rotating speeds of the polishing platen 23 and the polishing head 22 are preferable to be about 50 to 500 rpm, but is not limited thereto. Further, a supply amount of the polishing agent 25 is appropriately adjusted according to a composition of the polishing agent, the above-described polishing condition, and so on.

As the polishing pad 24, one made of nonwoven fabric, foamed polyurethane, a porous resin, a nonporous resin, or the like is usable. Hardness of the polishing pad 24 is not particularly limited, but the hardness is preferable to be low in view of reduction of a polishing defect, and, concretely, is preferable to be less than 40 in Shore D. In order to accelerate supply of the polishing agent 25 to the polishing pad 24 or to make a predetermined amount of the polishing agent 25 stay in the polishing pad 24, the surface of the polishing pad 24 may be subjected to a grooving processing of a lattice-shape, a concentric shape, a spiral shape, or the like. Further, as necessary, polishing may be performed while a pad conditioner is brought into contact with the surface of the polishing pad 24 to perform conditioning of the surface of the polishing pad 24.

According to the polishing method of the present invention, a surface to be polished made of a silicon oxide (for example, a silicon dioxide) can be polished at a high polishing rate in a CMP processing such as planarization of an interlayer insulation film and planarization of an insulation film for STI in manufacturing of a semiconductor device. Further, it is possible to achieve a high selectivity between the silicon oxide film and a silicon nitride film.

### Example

Hereinafter, the present invention will be described concretely by working examples and comparative examples, but the present invention is not limited to those working examples. Examples 1 to 6 are working examples, while examples 7 to 12 are comparative examples. In the following examples, “%” means “mass %” unless mentioned otherwise. Further, a characteristic value was measured by a method described below and given evaluation.

[pH]

A pH was measured by using a pH meter HM-30R manufactured by DKK-TOA Corporation.

[Average Particle Diameter]

An average particle diameter was measured by using a particle size distribution measuring apparatus of a laser scattering-diffraction type (manufactured by Horiba, Ltd., trade name: LA-950).

[Polishing Characteristic]

A polishing characteristic was evaluated by using a fully automatic CMP polishing apparatus (manufactured by Applied Materials, Inc., apparatus name: Mina). As a polishing pad, a pad made of a soft porous resin with a Shore D value of 34 was used, and for conditioning of the polishing pad a diamond pad conditioner (manufactured by 3M Company, trade name: A3700) was used. Polishing was performed for one minute under a polishing condition of 200 ml/min in flow rate of the polishing agent, 21 kPa in polishing pressure, 77 rpm in the rotating speed of the polishing platen, and 73 rpm in the rotating speed of the polishing head.

As a polishing target (object to be polished), an 8-inch blanket (silicon) substrate on which a silicon dioxide film was film-formed by plasma CVD with tetraethoxysilane, and an 8-inch blanket (silicon) substrate on which a silicon nitride film was film-formed by CVD, and a polishing rate of the silicon dioxide film and a polishing rate of the silicon nitride film were each measured. Then, a selectivity (polishing rate of silicon dioxide film/polishing rate of silicon nitride film) was calculated.

For measurement of the polishing rates, a thicknessmeter UV-1280SE manufactured by KLA-Tencor Corporation was used. By measuring a difference between a film thickness before polishing and a film thickness after one-minute polishing, the polishing rate was calculated. An average value (nm/min) of the polishing rates obtained by polishing rates of forty-nine points in a surface of the substrate was adopted as an evaluation index of the polishing rate.

### Example 1

To ion-exchange water, a cerium oxide dispersion liquid containing cerium oxide particles with an average particle diameter of 0.07 μm as abrasive particles was added so that a cerium oxide particle concentration in relation to an entire mass of a polishing agent was 0.5%, and further, a tetrahydrofuran-2-carboxylic acid was added so that a concentration was 0.05%, stirring was performed, and further, TMAH was added to adjust a pH at 4.8. A polishing agent (1) was obtained.

Next, polishing characteristics (a polishing rate of a silicon dioxide film, a polishing rate of a silicon nitride film, and a selectivity) of the polishing agent (1) obtained as above were measured by the above-described method. Measurement results are shown in Table 1 together with a composition of the polishing agent and a pH.

### Examples 2 to 5

To ion-exchange water, a cerium oxide dispersion liquid and a tetrahydrofuran-2-carboxylic acid the same as those in the example 1 were added so that each concentration shown in Table 1 was obtained and stirring was performed, and further, TMAH was added to adjust a pH to one shown in Table 1. Thereby, polishing agents (2) to (5) were prepared.

Next, polishing characteristics (a polishing rate of a silicon dioxide film, a polishing rate of a silicon nitride film, and a selectivity) of the obtained polishing agents (2) to (5) were measured by the above-described method. Measurement results are shown in Table 1.

### Example 6

To ion-exchange water, a cerium oxide dispersion liquid containing cerium oxide particles the same as those in the example 1 and cyclopentane carboxylic acid were each added so that a concentration in relation to an entire mass of a polishing agent might been a value in Table 1, and stirring was performed, and further, TMAH was added to adjust a pH at 4.8. Thereby, a polishing agent (6) was prepared.

Next, polishing characteristics (a polishing rate of a silicon dioxide film, a polishing rate of a silicon nitride film, and a selectivity) of the obtained polishing agent (6) were measured by the above-described method. Measurement results are shown in Table 1.

### Example 7

To ion-exchange water, a cerium oxide dispersion liquid containing cerium oxide particles the same as those in the example 1 was added so that a concentration shown in Table 1 was obtained, and stirring was performed, whereby a polishing agent (7) was obtained. A pH thereof was 4.5. Next, polishing characteristics (a polishing rate of a silicon dioxide film, a polishing rate of a silicon nitride film, and a selectivity) of the polishing agent (7) were measured by the above-described method. Measurement results are shown in Table 1.

### Examples 8 to 11

To ion-exchange water, a cerium oxide dispersion liquid containing cerium oxide particles the same as those in the example 1, and a chemical compound shown in Table 1 as an additive were added so that each concentration in relation to an entire mass of a polishing agent was a value shown in Table 1 and stiffing was performed, and further, TMAH was added to adjust a pH to one shown in Table 1. Thereby, polishing agents (8) to (11) were obtained.

Next, polishing characteristics (a polishing rate of a silicon dioxide film, a polishing rate of a silicon nitride film, and a selectivity) of the obtained polishing agents (8) to (11) were measured by the above-described method. Measurement results are shown in Table 1.

### Example 12

To ion-exchange water, a cerium oxide dispersion liquid containing cerium oxide particles the same as those in the example 1 and a tetrahydrofuran-2-carboxylic acid as an additive were each added so that a concentration of the cerium oxide particle in relation to an entire mass of a polishing agent was 0.5%, a concentration of the tetrahydrofuran-2-carboxylic acid was 0.05% and stirring was performed, and further, TMAH was added to adjust a pH at 8, whereby, a polishing agent (12) was obtained. Dispersion stability of the polishing agent (12) was checked by visual observation at a time that one week had passed after preparation, aggregation had already begun and precipitation had occurred. Redispersion thereof was difficult.

TABLE 1

| | | | Concentration | | Polishing rate | Polishing rate | |
|---|---|---|---|---|---|---|---|
| | | Concentration | of abrasive | | of Silicon | of Silicon | |
| | | of additive | particle | | dioxide | nitride | |
| Example | Kind of additive | (mass %) | (mass %) | pH | film(nm/min) | film(nm/min) | Selectivity |
| 1 | Tetrahydrofuran-2-carboxylic acid | 0.05 | 0.5 | 4.8 | 154.5 | 0.2 | 773 |
| 2 | Tetrahydrofuran-2-carboxylic acid | 0.1 | 0.5 | 4.8 | 105.1 | 0.1 | 1051 |
| 3 | Tetrahydrofuran-2-carboxylic acid | 0.05 | 0.5 | 4.2 | 152.2 | 0.2 | 761 |
| 4 | Tetrahydrofuran-2-carboxylic acid | 0.02 | 0.25 | 4.8 | 87 | 0.2 | 435 |
| 5 | Tetrahydrofuran-2-carboxylic acid | 0.02 | 0.5 | 4.2 | 116.9 | 0.1 | 1169 |
| 6 | Cyclopentane carboxylic acid | 0.05 | 0.5 | 4.8 | 58.5 | 0.1 | 585 |
| 7 | — | — | 0.5 | 4.5 | 10 | 6.2 | 2 |
| 8 | Cyclohexane carboxylic acid | 0.05 | 0.5 | 4.9 | 20.3 | 0.6 | 34 |
| 9 | Polyacrylic acid | 0.05 | 0.5 | 4.8 | 1.9 | 1.3 | 1 |
| 10 | 2-furancarboxylic acid | 0.02 | 0.5 | 4.2 | 71.3 | 0.2 | 355 |
| 11 | Tetrahydrofuran-2-carboxylic acid | 0.02 | 0.25 | 3.3 | 2.2 | 10.3 | 0.2 |

The following is known from Table 1. In the examples 1 to 6, as a result that polishing is performed by using the polishing agents (1) to (6) each of which contains the cerium oxide particles, water, the tetrahydrofuran-2-carboxylic acid or the cyclopentane carboxylic acid being a monocarboxylic acid (A) having a five-membered ring which does not include an unsaturated bond in the ring, and whose pH is 3.5 or more to 7 or less, a high polishing rate of the silicon dioxide film is obtained and the selectivity between the silicon dioxide film and the silicon nitride film becomes quite high.

In contrast, in the examples 7 to 9 each of which use the polishing agent (7) not containing the monocarboxylic acid (A), the polishing agent (8) containing the cyclohexane carboxylic acid being the monocarboxylic acid having a six-membered ring, and the polishing agent (9) containing the polyacrylic acid, it is known that the polishing rate of the silicon dioxide film is low and that the selectivity between the silicon dioxide film and the silicon nitride film is also low.

Further, in the example 10 which uses the polishing agent (10) containing the 2-firancarboxylic acid being the monocarboxylic acid which has the five-membered ring having the unsaturated bond, the polishing rate of the silicon dioxide film is low and the selectivity between the polishing rates of the silicon dioxide film and the silicon nitride film is also substantially low, compared with the example 5 which uses the polishing agent (5) containing the tetrahydrofuran-2-carboxylic acid at the same concentration as that of the 2-furancarboxylic acid, the concentration of the abrasive particle and the pH being also adjusted to be the same.

In the example 11 which uses the polishing agent (11) containing the tetrahydrofuran-2-carboxylic acid but whose pH is adjusted at less than 3.5, both the polishing rate of the silicon dioxide film and the selectivity are quite low. In the example 12 which uses the polishing agent (12) whose pH exceeds 7, it is known that precipitation due to aggregation of the abrasive particles occurs during storage and that usage itself as the polishing agent is difficult.

According to the present invention, in CMP of a surface to be polished including a surface made of a silicon oxide, for example, it is possible to suppress a polishing rate of a silicon nitride film at a low level while maintaining a sufficiently high polishing rate of the silicon oxide film, and a high selectivity between the silicon oxide film and a silicon nitride film can be achieved. Therefore, the polishing agent and the polishing method of the present invention are suitable for planarization of an insulation film for STI in manufacturing of a semiconductor device.

Configurations described in the aforementioned embodiments are merely presented schematically, and composition, materials or the like of each construction are examples only. Therefore, the present invention is not limited by the embodiments hereinabove and can be altered in various forms without departing from the scope of the technical idea indicated in the scope of what is claimed.

What is claimed is:

1. A polishing agent comprising:
cerium oxide particles;
water; and
a monocarboxylic acid having a five-membered ring not including an unsaturated bond in the ring or a derivative thereof, and/or a salt of the monocarboxylic acid,
wherein a pH is 3.5 or more to 7 or less.

2. The polishing agent according to claim 1,
wherein the monocarboxylic acid is at least one selected from a tetrahydrofuran-2-carboxylic acid and a cyclopentane carboxylic acid.

3. The polishing agent according to claim 1,
wherein a content ratio of the monocarboxylic acid and/or its salt is 0.001 mass % or more to 1.0 mass % or less.

4. The polishing agent according to claim 1,
wherein a content ratio of the cerium oxide particles is 0.05 mass % or more to 5 mass % or less.

5. A polishing method comprising polishing by a relative motion between a surface to be polished and a polishing pad which are brought into contact with each other while a polishing agent is supplied,
wherein a surface to be polished including a surface made of a silicon oxide of a semiconductor substrate is polished by using the polishing agent according to claim 1.
